(19) United States
(12) Patent Application Publication
(10) Pub. No.: US 2012/0244693 A1
(43) Pub. Date: Sep. 27, 2012

(54) METHOD FOR PATTERNING A FULL METAL GATE STRUCTURE

(75) Inventors: Vinh Hoang LUONG, Boise, ID (US); Akiteru KO, Schenectady, NY (US)

(73) Assignee: TOKYO ELECTRON LIMITED, Tokyo (JP)

(21) Appl. No.: 13/053,216

(22) Filed: Mar. 22, 2011

(51) Int. Cl. H01L 21/28

(52) U.S. Cl. 438/591; 438/592; 257/E21.19

(57) ABSTRACT

A method of patterning a gate structure on a substrate is described. The method includes preparing a metal gate structure on a substrate, wherein the metal gate structure includes a high dielectric constant (high-k) layer, a first gate layer formed on the high-k layer, and a second gate layer formed on the first gate layer, and wherein the first gate layer comprises one or more metal-containing layers. The method further includes preparing a mask layer with a pattern overlying the metal gate structure, transferring the pattern to the second gate layer, transferring the pattern to the first gate layer, and transferring the pattern in the first gate layer to the high-k layer, and prior to the transferring of the pattern to the high-k layer, passivating an exposed surface of the first gate layer using a nitrogen-containing and/or carbon-containing environment to reduce under-cutting of the first gate layer relative to the second gate layer, wherein the passivating is performed separately from or in addition to the transferring of the pattern to the first gate layer.

### BACKGROUND OF THE INVENTION

1. Field of Invention

The invention relates to a method for etching a metal gate structure on a substrate using a plasma etching process.

2. Description of Related Art

As the size of semiconductor devices is reduced, process development and integration issues are key challenges for new gate materials including high-permittivity (or high dielectric constant) dielectric materials (also referred to herein as high-k materials).

Dielectric materials featuring a dielectric constant greater than that of SiO₂ (k˜3.9) are commonly referred to as high-k materials. In addition, high-k materials may refer to dielectric materials that are deposited onto substrates (e.g., HfO₂, ZrO₂) rather than grown on the surface of the substrate (e.g., SiO₂, SiNₓO_{y}). High-k materials may incorporate metallic silicates or oxides (e.g., Ta₂O₅ (k˜26), TiO₂ (k˜80), ZrO₂ (k˜25), Al₂O₃ (k˜9), HfSiO, HfO₂ (k˜25)).

For front-end-of-line (FEOL) operations, these high-k materials are contemplated for integration with polycrystalline silicon (polysilicon) gate structures and, in the longer term, they are contemplated for use with metal gates. However, the integration of high-k materials with metal gate structures has posed substantive challenges during the patterning of the metal gate structure. In particular, conventional etching processes suffer from poor profile control during pattern transfer.

### SUMMARY OF THE INVENTION

The invention relates to a method for etching a metal gate structure on a substrate using a plasma etching process and, in particular, a method for etching a metal gate structure to achieve profile control with reduced under-cutting.

According to one embodiment, a method of patterning a gate structure on a substrate on a substrate is described. The method includes preparing a metal gate structure on a substrate, wherein the metal gate structure includes a high dielectric constant (high-k) layer, a first gate layer formed on the high-k layer, and a second gate layer formed on the first gate layer, and wherein the first gate layer comprises one or more metal-containing layers. The method further includes preparing a mask layer with a pattern overlying the metal gate structure, transferring the pattern to the second gate layer, transferring the pattern to the first gate layer, and transferring the pattern in the first gate layer to the high-k layer, and prior to the transferring of the pattern to the high-k layer, passivating an exposed surface of the first gate layer using a nitrogen-containing and/or carbon-containing environment to reduce under-cutting of the first gate layer relative to the second gate layer, wherein the passivating is performed separately from or in addition to the transferring of the pattern to the first gate layer.

According to another embodiment, a method of patterning a gate structure on a substrate, comprising: preparing a metal gate structure on a substrate, the metal gate structure including a high-k layer, a metal alloy layer formed on the high-k layer, and a gate layer formed on the metal alloy layer, the metal alloy layer comprising an Al-alloy and/or Ti-alloy; preparing a mask layer with a pattern overlying the metal gate structure; transferring the pattern to the gate layer; transferring the pattern to the metal alloy layer; transferring the pattern in the metal alloy layer to the high-k layer; and passivating an exposed surface of the metal alloy layer using a nitrogen-containing environment and/or carbon-containing environment to reduce under-cutting of the metal alloy layer relative to the gate layer.

### BRIEF DESCRIPTION OF THE DRAWINGS

In the accompanying drawings:

FIGS. 1A through 1B illustrate a schematic representation of a procedure for etching a metal gate structure on a substrate;

FIGS. 2A through 2E illustrate a schematic representation of a procedure for etching a metal gate structure on a substrate according to an embodiment;

FIG. 3 provides a flow chart illustrating a method of etching a metal gate structure on a substrate according to an embodiment;

FIG. 4 shows a schematic representation of a plasma processing system according to an embodiment;

FIG. 5 shows a schematic representation of a plasma processing system according to another embodiment;

FIG. 6 shows a schematic representation of a plasma processing system according to another embodiment;

FIG. 7 shows a schematic representation of a plasma processing system according to another embodiment;

FIG. 8 shows a schematic representation of a plasma processing system according to another embodiment;

FIG. 9 shows a schematic representation of a plasma processing system according to another embodiment; and

FIG. 10 shows a schematic representation of a plasma processing system according to another embodiment.

### DETAILED DESCRIPTION OF SEVERAL EMBODIMENTS

In the following description, for purposes of explanation and not limitation, specific details are set forth, such as a particular geometry of a processing system, descriptions of various components and processes used therein. However, it should be understood that the invention may be practiced in other embodiments that depart from these specific details.

Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

“Substrate” as used herein generically refers to the object being processed in accordance with the invention. The substrate may include any material portion or structure of a device, particularly a semiconductor or other electronics device, and may, for example, be a base substrate structure, such as a semiconductor wafer or a layer on or overlying a base substrate structure such as a thin film. Thus, substrate is not intended to be limited to any particular base structure, underlying layer or overlying layer, patterned or un-patterned, but rather, is contemplated to include any such layer or base structure, and any combination of layers and/or base structures. The description below may reference particular types of substrates, but this is for illustrative purposes only and not limitation.

In material processing methodologies, pattern etching can comprise the application of a thin layer of radiation-sensitive material, such as photo-resist, to an upper surface of a substrate, followed by patterning of the thin layer of material using lithographic techniques. During pattern etching, a dry plasma etching process can be utilized, wherein plasma is formed from a process gas by coupling electro-magnetic (EM) energy, such as radio frequency (RF) power, to the process gas in order to heat electrons and cause subsequent ionization and dissociation of the atomic and/or molecular constituents of the process gas. Using a series of dry etching processes, the pattern formed in the thin layer of radiation-sensitive material is transferred to the underlying layers within a film stack, including the one or more material layers that are desired for the end product, e.g., electronic device. Among other things, during the pattern transfer process, profile control for the pattern extended into underlying layers is of critical importance.

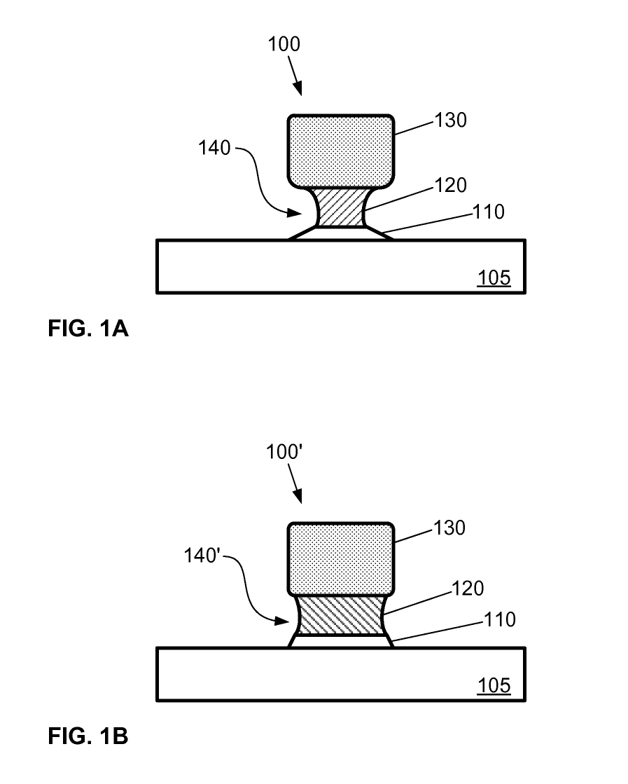

For example, as shown in FIGS. 1A and 1B, a metal gate structure 100 is prepared, wherein the metal gate structure 100 begins with forming a film stack having a plurality of layers (i.e., layers 110 through 130) on a substrate 105. The metal gate structure 100 may, for example, include a metal-containing gate having a gate dielectric layer 110, a first gate layer 120 overlying gate dielectric layer 110, and a second gate layer 130 overlying the first gate layer 120. The gate dielectric layer 110 may include one or more layers including, for example, a high dielectric constant (high-k) and an interfacial layer located between the high-k layer and the substrate 105. The first gate layer 120 may include a metal-containing layer, such as a metal or metal alloy. The second gate layer 130 may also include a metal-containing layer, such as a metal or metal alloy. For example, the second gate layer 130 may include a low resistance metal, such as tungsten.

As illustrated in FIG. 1A, a conventional etch process sequence causes severe profile under-cutting 140 of the second gate layer 130. During pattern transfer to the gate dielectric layer 110, poor etch selectivity between the gate dielectric layer 110 and the first gate layer 120 leads to isotropic erosion of the first gate layer 120. In FIG. 1B, a metal gate structure 100′ is illustrated depicting reduced profile under-cutting 140′ provided by embodiments of the invention.

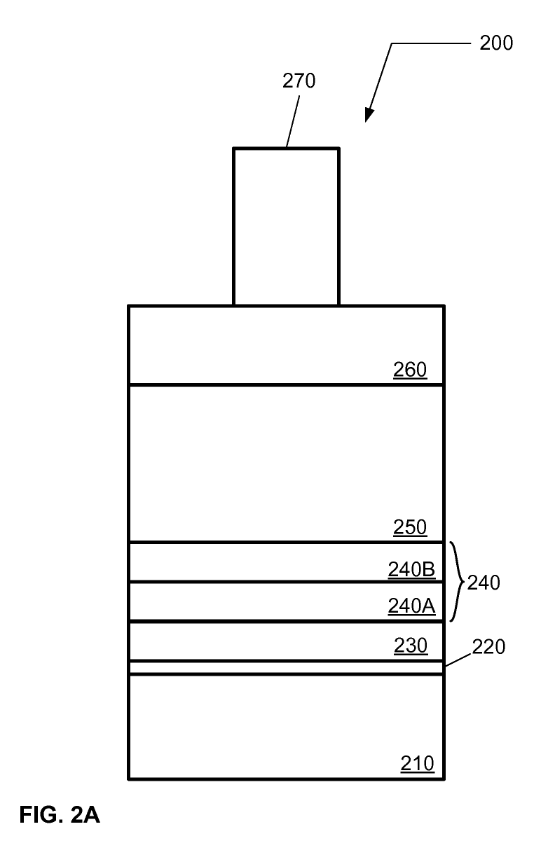

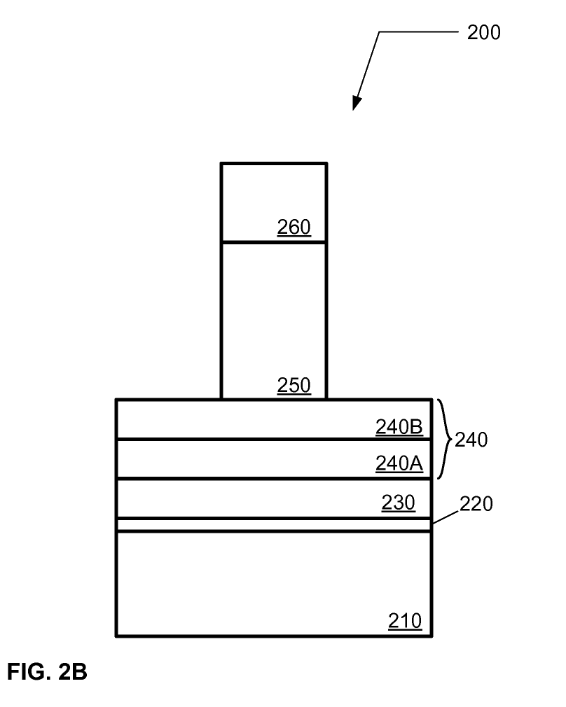

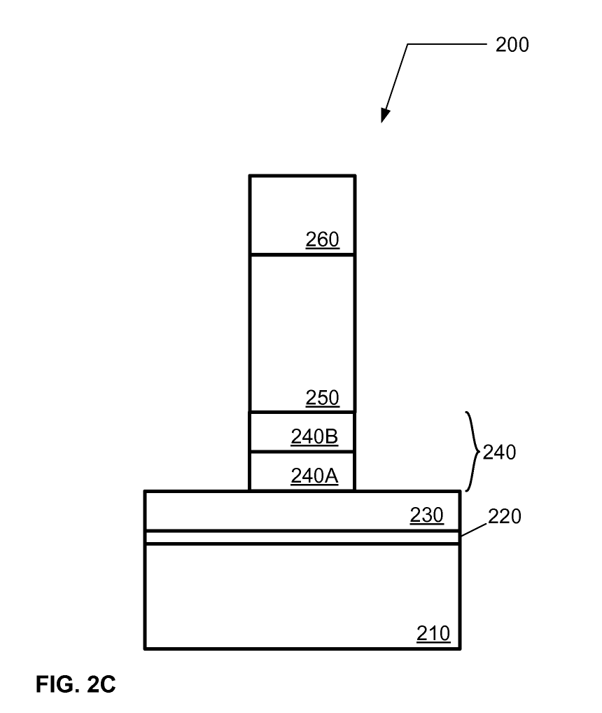

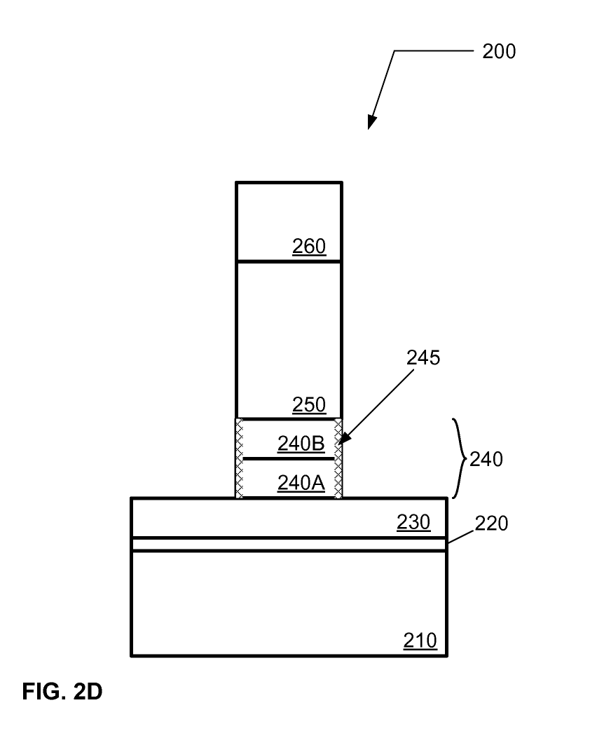

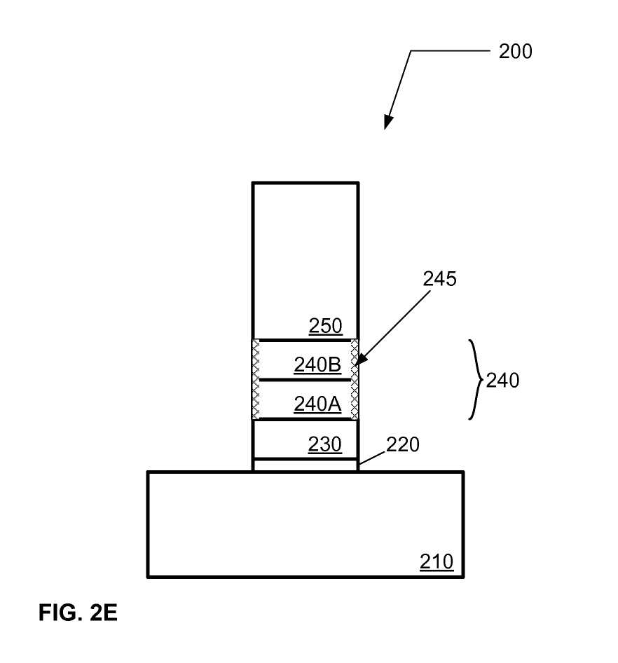

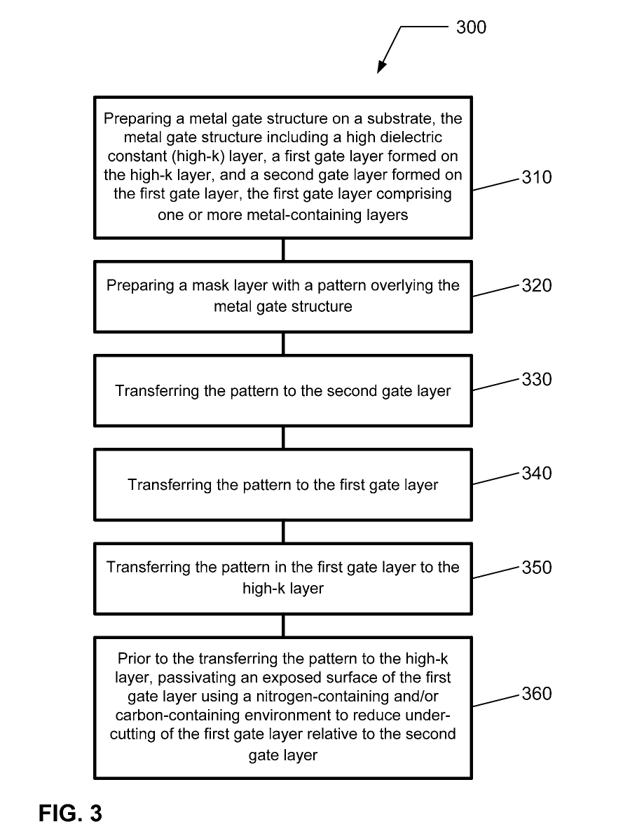

Therefore, according to an embodiment, a method for patterning a gate structure on a substrate is illustrated in FIGS. 2A through 2E, and FIG. 3. As described in FIG. 3 and illustrated pictorially in FIG. 2A, the method comprises a flow chart 300 beginning in 310 with preparing a metal gate structure 200 on a substrate 210, wherein the metal gate structure 200 includes a high dielectric constant (high-k) layer 230 as a gate dielectric, a first gate layer 240 formed on the high-k layer 230, and a second gate layer 250 formed on the first gate layer 240. The first gate layer 240 and the second gate layer 250 may, for example, be part of a gate electrode.

The first gate layer 240 may include one or more metal-containing layers, such as sub-layers 240A and 240B. The thickness of the first gate layer 240 may be several hundred Angstrom (Å), e.g., about 100 Å, 200 Å, 300 Å, 400 Å, etc. The first gate layer 240, as well as sub-layers thereof, may comprise a metal, a metal alloy, a metal nitride, or a metal oxide. For example, first gate layer 240 can contain titanium, titanium alloy, titanium aluminum alloy, tantalum, tantalum alloy, tantalum aluminum alloy, aluminum, aluminum alloy, titanium nitride, titanium silicon nitride, titanium aluminum nitride, tantalum nitride, tantalum silicon nitride, hafnium nitride, hafnium silicon nitride, aluminum nitride, or aluminum oxide. Additionally, the first gate layer 240 in the gate electrode can replace or be integrated with a traditional poly-Si gate electrode layer.

The second gate layer 250 may include a low resistance metal or metal alloy. For example, the second gate layer 250 may include a tungsten-containing layer, such as tungsten, tungsten alloy, or tungsten nitride.

While not shown in FIGS. 2A through 2E, the first gate layer 240 and the second gate layer 250 may be incorporated within a differential metal gate structure that comprises a first thickness for a first region on the substrate 210 and a second thickness for a second region on the substrate 210. The first thickness and the second thickness may be different. The first thickness of the first gate layer 240 at the first region may correspond to an nFET (negative channel field effect transistor) device, and the second thickness of the metal gate layer 240 at the second region may correspond to a pFET (positive channel FET) device, for example.

As illustrated in FIG. 2A, the gate dielectric including high-k layer 230 may further include an interfacial layer 220, such as a thin layer of silicon dioxide (SiO₂) between the high-k layer 230 and the substrate 210. The high-k layer 230 may, for example, comprise a lanthanum-containing layer, such as lanthanum oxide (LaO), or a hafnium containing layer, such as a hafnium oxide layer (e.g., HfOₓ, HfO₂), a hafnium silicate layer (e.g., HfSiO), or a nitrided hafnium silicate (e.g., HfSiO(N)). Additionally, for example, the high-k layer 230 may incorporate metallic silicates or oxides (e.g., Ta₂O₅ (k˜26), TiO₂ (k˜80), ZrO₂ (k˜25), Al₂O₃ (k˜9), HfSiO, HfO₂ (k˜25)). Furthermore, for example, the high-k layer 230 may include mixed rare earth oxides, mixed rare earth aluminates, mixed rare earth nitrides, mixed rare earth aluminum nitrides, mixed rare earth oxynitrides, or mixed rare earth aluminum oxynitrides.

In 320, a mask layer 270 with a pattern is prepared overlying the metal gate structure 200. The mask layer 270 may include a layer of radiation-sensitive material or photo-resist having a pattern formed therein using a photo-lithographic process or other lithographic process (e.g., electron beam lithography, imprint lithography, etc.). Additionally, for example, the mask layer 270 of the metal gate structure 200 may include a second layer, and even a third layer. For example, the mask layer 270 may include an anti-reflective coating (ARC) layer to provide, among other things, anti-reflective properties for the lithographic patterning of the layer of radiation-sensitive material to form the pattern. The mask layer 270 may further include one or more soft mask layers, and/or one or more organic planarization layers (OPL) or organic dielectric layers (ODL). Further yet, the metal gate structure 200 may include one or more hard mask layers 260, such as a silicon dioxide (SiO₂) hard mask for dry etching the second gate layer 250. The pattern is formed in mask layer 270 utilizing one or more lithographic processes and optionally one or more mask etching processes, and then is transferred to the one or more hard mask layers 260 for patterning the underlying metal gate structure 200.

As illustrated in FIGS. 2B and 2C, a series of etching processes for transferring the pattern defined in mask layer 270 to the underlying stack of films to form a patterned metal gate structure is selected to preserve the integrity of the pattern being transferred, e.g., critical dimensions, etc., as well as minimize damage to those layers which are utilized in the electronic device being fabricated.

In 330, as shown in FIG. 3 and illustrated in FIG. 2B, the pattern in mask layer 270, which has been transferred to the one or more hard mask layers 260, is transferred to the second gate layer 250 using one or more second gate layer etching processes. The one or more second gate layer etching processes comprises at least one etch step that includes forming plasma using a halogen-containing gas and an optional additive gas having: C and F; C, H, and F; or N and F, as atomic constituents. The one or more second gate layer etching processes may further include a noble gas. The halogen-containing gas may include one or more gases selected from the group consisting of Cl₂, Br₂, HBr, HCl, and BCl₃. Furthermore, the optional additive gas may include one or more gases selected from the group consisting of CF₄, C₄F₈, C₄F₆, C₅F₈, NF₃, CH₂F₂, and CH F₃. For example, the one or more second gate layer etching processes may include using Cl₂, CF₄, and Ar. Additionally, for example, the one or more second gate layer etching processes may include using Cl₂, CH₂F₂, and Ar.

In 340, as shown in FIG. 3 and illustrated in FIG. 2C, the pattern in the second gate layer 250 is transferred to the first gate layer 240 using one or more first gate layer etching processes. The one or more first gate layer etching processes comprises at least one etch step that includes forming plasma using a halogen-containing gas and an optional additive gas. The one or more first gate layer etching processes may further include a noble gas. The halogen-containing gas may include one or more gases selected from the group consisting of Cl₂, Br₂, HBr, HCl, and BCl₃. For example, the one or more first gate layer etching processes may include a single first gate layer etching process using a first halogen-containing gas, a second halogen-containing gas, and a noble gas. Additionally, for example, the one or more first gate layer etching processes may include using Cl₂, BCl₃, and Ar.

In 350, as shown in FIG. 3 and illustrated in FIG. 2E, the pattern in the first gate layer 240 is transferred to the high-k layer 230 using one or more high-k layer etching processes. The one or more high-k layer etching processes comprises at least one etch step that includes forming plasma using a halogen-containing gas and an optional additive gas. The one or more high-k layer etching processes may further include a noble gas. The halogen-containing gas may include one or more gases selected from the group consisting of Cl₂, Br₂, HBr, HCl, and BCl₃. For example, the one or more high-k layer etching processes may include using BCl_{3 and He.}

In 360, as shown in FIG. 3 and illustrated in FIG. 2D, an exposed surface 245 of the first gate layer 240 is passivated by contacting the exposed surface 245 of the first gate layer 240 with a nitrogen-containing and/or carbon-containing environment to reduce profile under-cutting of the first gate layer 240 relative to the second gate layer 250. As illustrated in FIG. 2D, the exposed surface 245 of the first gate layer 240 may include a sidewall surface which is exposed following pattern transfer to the first gate layer 240. The nitrogen-containing and/or carbon-containing environment may include a non-plasma environment. Alternatively, the nitrogen-containing and/or carbon-containing environment may include a plasma environment. The nitrogen-containing and/or carbon-containing environment may further include hydrogen.

For example, the nitrogen-containing environment may include a nitrogen-containing plasma. The nitrogen-containing plasma may contain as an incipient ingredient N₂, or NH₃, or a combination thereof. The nitrogen-containing plasma may further contain as an incipient ingredient H₂. Additionally, for example, the carbon-containing environment may include a carbon-containing plasma. The carbon-containing plasma may contain as an incipient ingredient a hydrocarbon-containing gas, such as C₂H₄, CH₄, C₂H₂, C₂H₆, C₃H₄, C₃H₆, C₃H₈, C₄H₆, C₄H₈, C₄H₁₀, C₅H₈, C₅H₁₀, C₆H₆, C₆H₁₀, and C₆H₁₂.

The passivation of the exposed surface 245 of the first gate layer 240 may be performed prior to transferring the pattern to the high-k layer 230. Additionally, the passivation of the exposed surface 245 of the first gate layer 240 may be performed separately from or in addition to the transferring of the pattern to the first gate layer 240.

According to one embodiment, following the transfer of the pattern to the first gate layer 240 in 340 and preceding the transfer of the pattern to the high-k layer 230 in 350, the exposed surface 245 of the first gate layer 240 is passivated using a non-plasma or plasma treatment process. The non-plasma or plasma treatment process contains as an incipient ingredient a nitrogen-containing gas and/or a carbon-containing gas. For example, the plasma treatment process may include a nitrogen-containing plasma. The nitrogen-containing plasma may contain as an incipient ingredient N₂, or NH₃, or a combination thereof. The nitrogen-containing plasma may further contain as an incipient ingredient H₂. Additionally, for example, the plasma treatment process may include a carbon-containing plasma. The carbon-containing plasma may contain as an incipient ingredient a hydrocarbon-containing gas, such as C₂H₄, CH₄, C₂H₂, C₂H₆, C₃H₄, C₃H₆, C₃H₈, C₄H₆, C₄H₈, C₄H₁₀, C₅H₈, C₅H₁₀, C₆H₆, C₆H₁₀, and C₆H₁₂.

According to another embodiment, during the transfer of the pattern to the first gate layer 240 in 340, the optional additive gas may include a nitrogen-containing gas or a carbon-containing gas. Therein, as the pattern is transferred through the first gate layer 240, the exposed surface 245 of the first gate layer 240 is passivated.

According to another embodiment, during the transfer of the pattern to the high-k layer 230 in 350, the optional additive gas may include a nitrogen-containing gas or a carbon-containing gas. Therein, as the pattern is transferred through the high-k layer 230, the exposed surface 245 of the first gate layer 240 is passivated.

According to another embodiment, during the transfer of the pattern to the high-k layer 230 in 350, the substrate temperature may be selected to be less than about 250 degrees C. Alternatively, the substrate temperature may be selected to be less than about 220 degrees C.

According to yet another embodiment, any combination of the passivation strategies described above may be utilized.

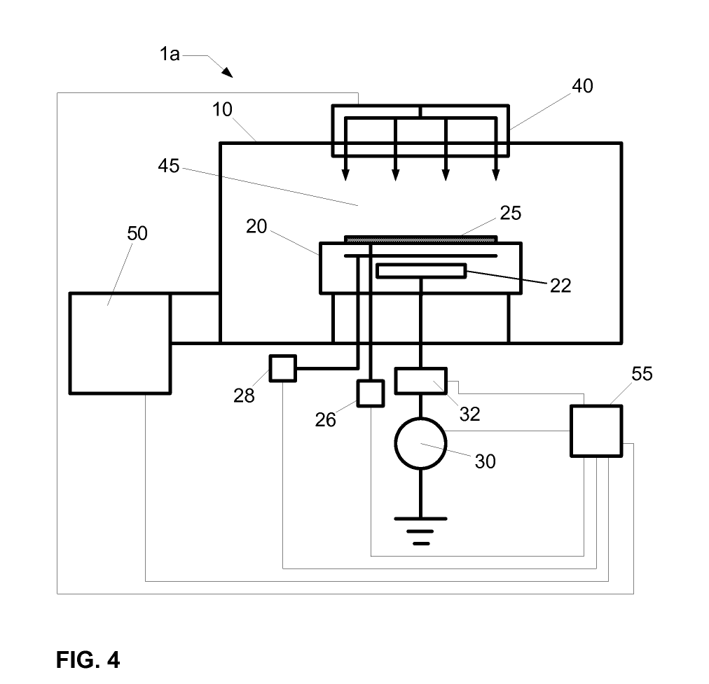

According to one embodiment, a plasma processing system 1a configured to perform the above identified process conditions is depicted in FIG. 4 comprising a plasma processing chamber 10, substrate holder 20, upon which a substrate 25 to be processed is affixed, and vacuum pumping system 50. Substrate 25 can be a semiconductor substrate, a wafer, a flat panel display, or a liquid crystal display. Plasma processing chamber 10 can be configured to facilitate the generation of plasma in plasma processing region 45 in the vicinity of a surface of substrate 25. An ionizable gas or mixture of process gases is introduced via a gas distribution system 40. For a given flow of process gas, the process pressure is adjusted using the vacuum pumping system 50. Plasma can be utilized to create materials specific to a pre-determined materials process, and/or to aid the removal of material from the exposed surfaces of substrate 25. The plasma processing system 1a can be configured to process substrates of any desired size, such as 200 mm substrates, 300 mm substrates, or larger.

Substrate 25 can be affixed to the substrate holder 20 via a clamping system 28, such as a mechanical clamping system or an electrical clamping system (e.g., an electrostatic clamping system). Furthermore, substrate holder 20 can include a heating system (not shown) or a cooling system (not shown) that is configured to adjust and/or control the temperature of substrate holder 20 and substrate 25. The heating system or cooling system may comprise a re-circulating flow of heat transfer fluid that receives heat from substrate holder 20 and transfers heat to a heat exchanger system (not shown) when cooling, or transfers heat from the heat exchanger system to substrate holder 20 when heating. In other embodiments, heating/cooling elements, such as resistive heating elements, or thermo-electric heaters/coolers can be included in the substrate holder 20, as well as the chamber wall of the plasma processing chamber 10 and any other component within the plasma processing system 1a.

Additionally, a heat transfer gas can be delivered to the backside of substrate 25 via a backside gas supply system 26 in order to improve the gas-gap thermal conductance between substrate 25 and substrate holder 20. Such a system can be utilized when temperature control of the substrate is required at elevated or reduced temperatures. For example, the backside gas supply system can comprise a two-zone gas distribution system, wherein the helium gas-gap pressure can be independently varied between the center and the edge of substrate 25.

In the embodiment shown in FIG. 4, substrate holder 20 can comprise an electrode 22 through which RF power is coupled to the processing plasma in plasma processing region 45. For example, substrate holder 20 can be electrically biased at a RF voltage via the transmission of RF power from a RF generator 30 through an optional impedance match network 32 to substrate holder 20. The RF bias can serve to heat electrons to form and maintain plasma. In this configuration, the system can operate as a reactive ion etch (RIE) reactor, wherein the chamber and an upper gas injection electrode serve as ground surfaces. A typical frequency for the RF bias can range from about 0.1 MHz to about 100 MHz. RF systems for plasma processing are well known to those skilled in the art.

Alternately, RF power is applied to the substrate holder electrode at multiple frequencies. Furthermore, impedance match network 32 can improve the transfer of RF power to plasma in plasma processing chamber 10 by reducing the reflected power. Match network topologies (e.g. L-type, π-type, T-type, etc.) and automatic control methods are well known to those skilled in the art.

Gas distribution system 40 may comprise a showerhead design for introducing a mixture of process gases. Alternatively, gas distribution system 40 may comprise a multi-zone showerhead design for introducing a mixture of process gases and adjusting the distribution of the mixture of process gases above substrate 25. For example, the multi-zone showerhead design may be configured to adjust the process gas flow or composition to a substantially peripheral region above substrate 25 relative to the amount of process gas flow or composition to a substantially central region above substrate 25.

Vacuum pumping system 50 can include a turbo-molecular vacuum pump (TMP) capable of a pumping speed up to about 5000 liters per second (and greater) and a gate valve for throttling the chamber pressure. In conventional plasma processing devices utilized for dry plasma etching, a 1000 to 3000 liter per second TMP can be employed. TMPs are useful for low pressure processing, typically less than about 50 mTorr. For high pressure processing (i.e., greater than about 100 mTorr), a mechanical booster pump and dry roughing pump can be used. Furthermore, a device for monitoring chamber pressure (not shown) can be coupled to the plasma processing chamber 10.

Controller 55 comprises a microprocessor, memory, and a digital I/O port capable of generating control voltages sufficient to communicate and activate inputs to plasma processing system 1a as well as monitor outputs from plasma processing system 1a. Moreover, controller 55 can be coupled to and can exchange information with RF generator 30, impedance match network 32, the gas distribution system 40, vacuum pumping system 50, as well as the substrate heating/cooling system (not shown), the backside gas delivery system 26, and/or the electrostatic clamping system 28. For example, a program stored in the memory can be utilized to activate the inputs to the aforementioned components of plasma processing system 1a according to a process recipe in order to perform a plasma assisted process on substrate 25.

Controller 55 can be locally located relative to the plasma processing system 1a, or it can be remotely located relative to the plasma processing system 1a. For example, controller 55 can exchange data with plasma processing system 1a using a direct connection, an intranet, and/or the internet. Controller 55 can be coupled to an intranet at, for example, a customer site (i.e., a device maker, etc.), or it can be coupled to an intranet at, for example, a vendor site (i.e., an equipment manufacturer). Alternatively or additionally, controller 55 can be coupled to the internet. Furthermore, another computer (i.e., controller, server, etc.) can access controller 55 to exchange data via a direct connection, an intranet, and/or the internet.

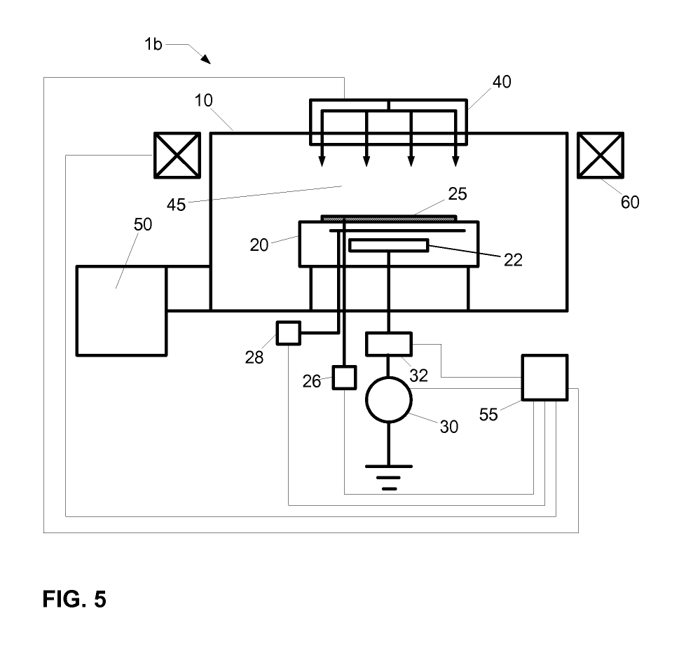

In the embodiment shown in FIG. 5, plasma processing system 1b can be similar to the embodiment of FIG. 4 and further comprise either a stationary, or mechanically or electrically rotating magnetic field system 60, in order to potentially increase plasma density and/or improve plasma processing uniformity, in addition to those components described with reference to FIG. 4. Moreover, controller 55 can be coupled to magnetic field system 60 in order to regulate the speed of rotation and field strength. The design and implementation of a rotating magnetic field is well known to those skilled in the art.

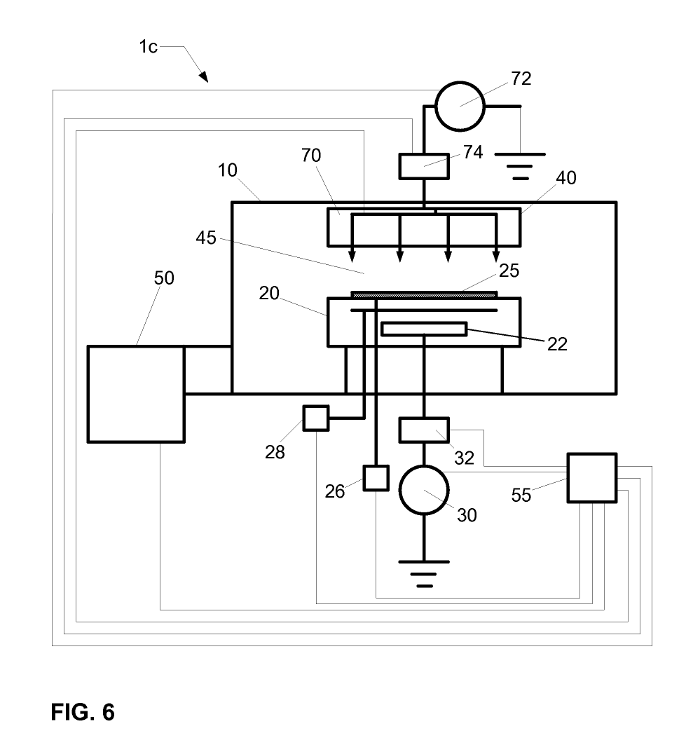

In the embodiment shown in FIG. 6, plasma processing system 1c can be similar to the embodiment of FIG. 4 or FIG. 5, and can further comprise an upper electrode 70 to which RF power can be coupled from RF generator 72 through optional impedance match network 74. A frequency for the application of RF power to the upper electrode can range from about 0.1 MHz to about 200 MHz. Additionally, a frequency for the application of power to the lower electrode can range from about 0.1 MHz to about 100 MHz. Moreover, controller 55 is coupled to RF generator 72 and impedance match network 74 in order to control the application of RF power to upper electrode 70. The design and implementation of an upper electrode is well known to those skilled in the art. The upper electrode 70 and the gas distribution system 40 can be designed within the same chamber assembly, as shown.

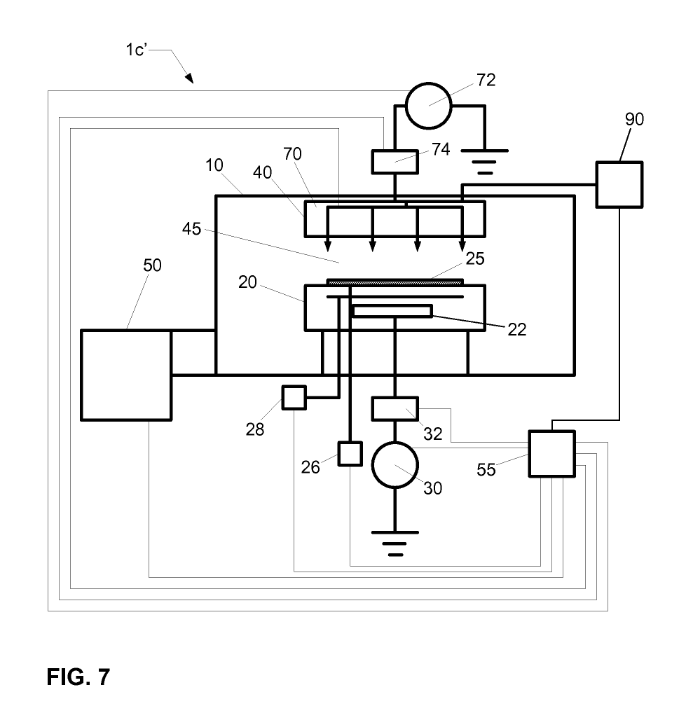

In the embodiment shown in FIG. 7, plasma processing system 1c′ can be similar to the embodiment of FIG. 6, and can further comprise a direct current (DC) power supply 90 coupled to the upper electrode 70 opposing substrate 25. The upper electrode 70 may comprise an electrode plate. The electrode plate may comprise a silicon-containing electrode plate. Moreover, the electrode plate may comprise a doped silicon electrode plate. The DC power supply 90 can include a variable DC power supply. Additionally, the DC power supply can include a bipolar DC power supply. The DC power supply 90 can further include a system configured to perform at least one of monitoring, adjusting, or controlling the polarity, current, voltage, or on/off state of the DC power supply 90. Once plasma is formed, the DC power supply 90 facilitates the formation of a ballistic electron beam. An electrical filter (not shown) may be utilized to de-couple RF power from the DC power supply 90.

For example, the DC voltage applied to upper electrode 70 by DC power supply 90 may range from approximately −2000 volts (V) to approximately 1000 V. Desirably, the absolute value of the DC voltage has a value equal to or greater than approximately 100 V, and more desirably, the absolute value of the DC voltage has a value equal to or greater than approximately 500 V. Additionally, it is desirable that the DC voltage has a negative polarity. Furthermore, it is desirable that the DC voltage is a negative voltage having an absolute value greater than the self-bias voltage generated on a surface of the upper electrode 70. The surface of the upper electrode 70 facing the substrate holder 20 may be comprised of a silicon-containing material.

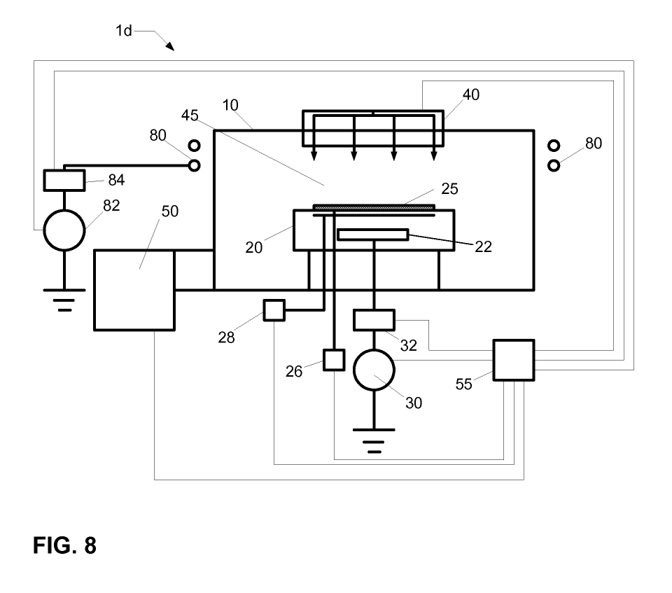

In the embodiment shown in FIG. 8, plasma processing system 1d can be similar to the embodiments of FIGS. 4 and 5, and can further comprise an inductive coil 80 to which RF power is coupled via RF generator 82 through optional impedance match network 84. RF power is inductively coupled from inductive coil 80 through a dielectric window (not shown) to plasma processing region 45. A frequency for the application of RF power to the inductive coil 80 can range from about 10 MHz to about 100 MHz. Similarly, a frequency for the application of power to the chuck electrode can range from about 0.1 MHz to about 100 MHz. In addition, a slotted Faraday shield (not shown) can be employed to reduce capacitive coupling between the inductive coil 80 and plasma in the plasma processing region 45. Moreover, controller 55 can be coupled to RF generator 82 and impedance match network 84 in order to control the application of power to inductive coil 80.

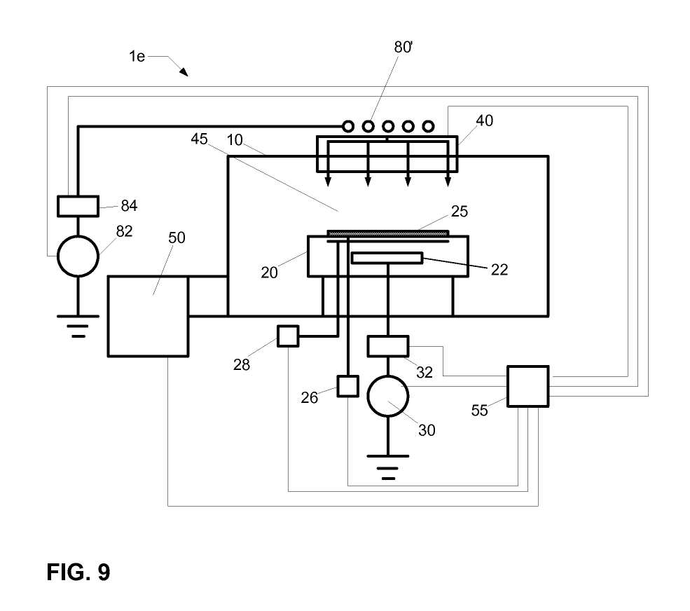

In an alternate embodiment, as shown in FIG. 9, plasma processing system 1e can be similar to the embodiment of FIG. 8, and can further comprise an inductive coil 80′ that is a “spiral” coil or “pancake” coil in communication with the plasma processing region 45 from above as in a transformer coupled plasma (TCP) reactor. The design and implementation of an inductively coupled plasma (ICP) source, or transformer coupled plasma (TCP) source, is well known to those skilled in the art.

Alternately, plasma can be formed using electron cyclotron resonance (ECR). In yet another embodiment, the plasma is formed from the launching of a Helicon wave. In yet another embodiment, the plasma is formed from a propagating surface wave. Each plasma source described above is well known to those skilled in the art.

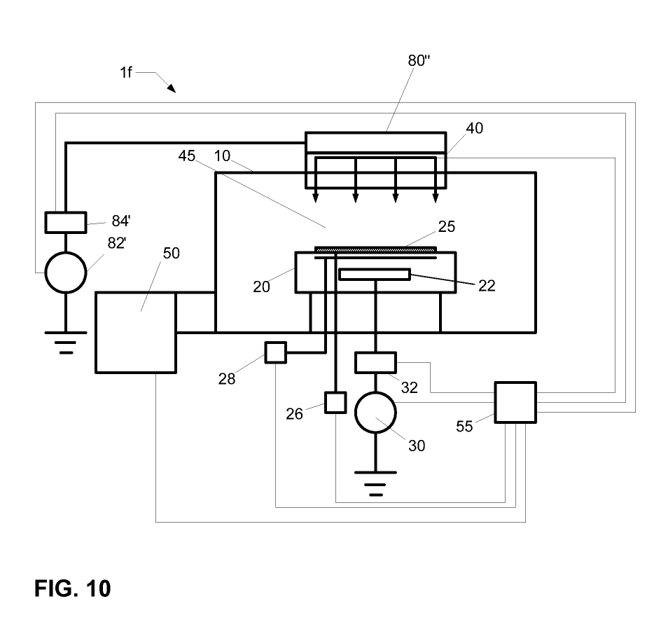

In the embodiment shown in FIG. 10, plasma processing system 1f can be similar to the embodiment of FIG. 4, and can further comprise a surface wave plasma (SWP) source 80″. The SWP source 80″ can comprise a slot antenna, such as a radial line slot antenna (RLSA), to which microwave power is coupled via microwave generator 82′ through optional impedance match network 84′.

In one embodiment, the one or more second gate layer etching processes may comprise a process parameter space that includes: a chamber pressure ranging up to about 1000 mtorr (millitorr) (e.g., up to about 100 mtorr, or up to about 10 to 30 mtorr), a halogen-containing gas process gas flow rate ranging up to about 2000 sccm (standard cubic centimeters per minute) (e.g., up to about 1000 sccm, or about 1 sccm to about 100 sccm, or about 50 sccm to about 100 sccm, or about 80 sccm), an optional additive gas process gas flow rate ranging up to about 2000 sccm (e.g., up to about 1000 sccm, or about 1 sccm to about 30 sccm), a noble gas process gas flow rate ranging up to about 2000 sccm (e.g., up to about 1000 sccm), an upper electrode (e.g., element 70 in FIG. 6) RF bias ranging up to about 2000 W (watts) (e.g., up to about 1000 W, or up to about 600 W), and a lower electrode (e.g., element 22 in FIG. 6) RF bias ranging up to about 1000 W (e.g., up to about 600 W, or up to about 100 W). Also, the upper electrode bias frequency can range from about 0.1 MHz to about 200 MHz, e.g., about 60 MHz. In addition, the lower electrode bias frequency can range from about 0.1 MHz to about 100 MHz, e.g., about 2 MHz.

As an example, Table 1 provides exemplary process conditions for three (3) different second gate layer etching processes for etching the second gate layer when, for example, the second gate layer includes tungsten. Each of the second gate layer etching processes uses plasma formed from a process composition. The process composition for the three (3) second gate layer etching processes are as follows: (A) Cl₂, Ar, CH₂F₂; (B) Cl₂, Ar, CF₄; (C) Cl₂, Ar, CF₄.

TABLE 1

| | | | | T (° C.) (UEL, | | | | | |
|---|---|---|---|---|---|---|---|---|---|
| | UEL RF | LEL RF | p | W, LEL-C, LEL [symbol] | Cl₂ | Ar | CF₄ | CH₂F₂ | |
| Process Description | (W) | (W) | (mTorr) | E) | (sccm) | (sccm) | (sccm) | (sccm) | Profile |
| (A) Second gate layer | 600 | 100 | 15 | 80, 60, 70, 70 | 80 | 500 | 0 | 4 | Tapered |
| etching process | | | | | | | | | |
| (B) Second gate layer | 600 | 100 | 15 | 80, 60, 70, 70 | 80 | 500 | 20 | 0 | <Tapered |
| etching process | | | | | | | | | |
| (C) Second gate layer | 600 | 50 | 15 | 80, 60, 70, 70 | 20 | 500 | 20 | 0 | <<Tapered |
| etching process | | | | | | | | | |

[symbol]

indicates data missing or illegible when filed

For each second gate layer etching process, a process condition is recited including an upper electrode (UEL) power (watts, W), a lower electrode (LEL) power (watts, W), a gas pressure (millitorr, mtorr) in the plasma processing chamber, a temperature set for components in the plasma processing chamber (° C.) (“UEL”=Upper electrode temperature; “W”=Wall temperature; “LEL-C”=Lower electrode center temperature; “LEL-E”=Lower electrode edge temperature), a Cl₂ flow rate (standard cubic centimeters per minute, sccm), an Ar flow rate, a CF₄ flow rate, a CH₂F₂ flow rate, and a note regarding the resulting profile. As illustrated in Table 1, the sidewall taper improves from the second gate layer etching process (A) through (C). The ratios between Cl, C, and F are important for profile control of the second gate layer.

In another embodiment, the one or more first gate layer etching processes may comprise a process parameter space that includes: a chamber pressure ranging up to about 1000 mtorr (millitorr) (e.g., up to about 100 mtorr, or up to about 20 to 100 mtorr), a first halogen-containing gas process gas flow rate ranging up to about 2000 sccm (standard cubic centimeters per minute) (e.g., up to about 1000 sccm, or about 1 sccm to about 100 sccm, or about 1 sccm to about 50 sccm, or about 40 sccm), a second halogen-containing gas process gas flow rate ranging up to about 2000 sccm (standard cubic centimeters per minute) (e.g., up to about 1000 sccm, or about 1 sccm to about 100 sccm, or about 1 sccm to about 50 sccm, or about 20 sccm), an optional additive gas process gas flow rate ranging up to about 2000 sccm (e.g., up to about 1000 sccm, or about 1 sccm to about 100 sccm), a noble gas process gas flow rate ranging up to about 2000 sccm (e.g., up to about 1000 sccm), an upper electrode (e.g., element 70 in FIG. 6) RF bias ranging up to about 2000 W (watts) (e.g., up to about 1000 W, or up to about 600 W), and a lower electrode (e.g., element 22 in FIG. 6) RF bias ranging up to about 1000 W (e.g., up to about 600 W, or up to about 100 W). Also, the upper electrode bias frequency can range from about 0.1 MHz to about 200 MHz, e.g., about 60 MHz. In addition, the lower electrode bias frequency can range from about 0.1 MHz to about 100 MHz, e.g., about 2 MHz.

As an example, Table 2 provides an exemplary process condition for a first gate layer etching process for etching the first gate layer when, for example, the first gate layer includes a first sub-layer containing aluminum alloy and a second sub-layer containing titanium alloy. The first gate layer etching process includes a single process step using plasma formed from a process composition. The process composition is as follows: Cl₂, Ar, BCl₃.

TABLE 2

| | | | | T (° C.) (UEL, | | | | |
|---|---|---|---|---|---|---|---|---|
| | UEL RF | LEL RF | p | W, LEL-C, LEL [symbol] | Cl₂ | Ar | BCl₄ | |
| Process Description | (W) | (W) | (mTorr) | E) | (sccm) | (sccm) | (sccm) | Profile |
| First gate layer etching | 200 | 100 | 50 | 80, 60, 70, 70 | 40 | 200 | 20 | Acceptable |
| process | | | | | | | | |

[symbol]

indicates data missing or illegible when filed

For each first gate layer etching process, a process condition is recited including an upper electrode (UEL) power (watts, W), a lower electrode (LEL) power (watts, W), a gas pressure (millitorr, mtorr) in the plasma processing chamber, a temperature set for components in the plasma processing chamber (° C.) (“UEL”=Upper electrode temperature; “W”=Wall temperature; “LEL-C”=Lower electrode center temperature; “LEL-E”=Lower electrode edge temperature), a Cl₂ flow rate (standard cubic centimeters per minute, sccm), an Ar flow rate, a BCl₃ flow rate, and a note regarding the resulting profile. The Cl may be used as the primary etchant, while the B may be used to scavenge O (oxygen) in the first gate layer.

In another embodiment, the one or more high-k layer etching processes may comprise a process parameter space that includes: a chamber pressure ranging up to about 1000 mtorr (millitorr) (e.g., up to about 100 mtorr, or up to about 5 to 30 mtorr), a halogen-containing gas process gas flow rate ranging up to about 2000 sccm (standard cubic centimeters per minute) (e.g., up to about 1000 sccm, or about 1 sccm to about 300 sccm, or about 100 sccm to about 200 sccm, or about 150 sccm), an optional additive gas process gas flow rate ranging up to about 2000 sccm (e.g., up to about 1000 sccm, or about 1 sccm to about 10 sccm), a noble gas process gas flow rate ranging up to about 2000 sccm (e.g., up to about 1000 sccm), an upper electrode (e.g., element 70 in FIG. 6) RF bias ranging up to about 2000 W (watts) (e.g., up to about 1000 W, or up to about 600 W), and a lower electrode (e.g., element 22 in FIG. 6) RF bias ranging up to about 1000 W (e.g., up to about 600 W, or up to about 100 W). Also, the upper electrode bias frequency can range from about 0.1 MHz to about 200 MHz, e.g., about 60 MHz. In addition, the lower electrode bias frequency can range from about 0.1 MHz to about 100 MHz, e.g., about 2 MHz.

As an example, Table 3 provides exemplary process conditions for four (4) different high-k layer etching processes for etching the high-k layer when, for example, the high-k layer includes hafnium oxide (HfO₂). Each of the high-k layer etching processes uses plasma formed from a process composition. The process composition for the four (4) high-k layer etching processes are as follows: (A) BCl₃, He; (B) BCl₃, He, C₂H₄; (C) BCl₃, He; and (D) BCl₃, He.

TABLE 3

| | | | | | | | | Profile |
|---|---|---|---|---|---|---|---|---|
| | | | | | | | | under- |
| | UEL RF | LEL RF | p | T (° C.) (UEL, | BCl₃ | He | C₂H₄ | cutting |
| Process Description | (W) | (W) | (mTorr) | W, LEL) | (sccm) | (sccm) | (sccm) | (nm) |
| (A) High-k layer etching | 300 | 0 | 10 | 80, 60, 370 | 100 | 200 | 0 | 4.3 |
| process | | | | | | | | |
| (B) High-k layer etching | 300 | 0 | 10 | 80, 60, 370 | 100 | 200 | 3 | 1.5 |
| process | | | | | | | | |
| (C) High-k layer etching | 600 | 0 | 10 | 80, 60, 220 | 150 | 150 | 0 | 0.8 |
| process | | | | | | | | |
| (D) High-k layer etching | 600 | 0 | 10 | 80, 60, 370 | 150 | 150 | 0 | ~3.7 |
| process | | | | | | | | |

For each high-k layer etching process, a process condition is recited including an upper electrode (UEL) power (watts, W), a lower electrode (LEL) power (watts, W), a gas pressure (millitorr, mtorr) in the plasma processing chamber, a temperature set for components in the plasma processing chamber (° C.) (“UEL”=Upper electrode temperature; “W”=Wall temperature; “LEL”=Lower electrode temperature), a BCl₃ flow rate (standard cubic centimeters per minute, sccm), a He flow rate, a C₂H₄ flow rate, and a note regarding the resulting profile. When a hydrocarbon gas is introduced and/or the substrate temperature is reduced, the profile under-cutting is reduced (or improved).

In yet another embodiment, following the transfer of the pattern to the first gate layer and preceding the transfer of the pattern to the high-k layer, the exposed surface of the first gate layer is passivated using a non-plasma or plasma treatment process. The non-plasma or plasma treatment process contains as an incipient ingredient a nitrogen-containing gas and/or a carbon-containing gas. As an example, the plasma treatment process may contain as an incipient ingredient N₂ and H₂. The inventors have observed a reduction in profile under-cutting when inserting this plasma treatment process between the one or more first gate layer etching processes and the one or more high-k layer etching processes. Alternatively, as an example, the plasma treatment process may contain as an incipient ingredient a hydrocarbon-containing gas, such as C₂H₄.

In alternate embodiments, RF power may be supplied to the upper electrode and not the lower electrode. In other alternate embodiments, RF power may be supplied to the lower electrode and not the upper electrode. In yet other alternate embodiments, RF power and/or DC power may be coupled in any of the manners described through FIGS. 4 to 10.

The time duration to perform a specific etching process may be determined using design of experiment (DOE) techniques or prior experience; however, it may also be determined using endpoint detection. One possible method of endpoint detection is to monitor a portion of the emitted light spectrum from the plasma region that indicates when a change in plasma chemistry occurs due to change or substantially near completion of the removal of a particular material layer from the substrate and contact with the underlying thin film. After emission levels corresponding to the monitored wavelengths cross a specified threshold (e.g., drop to substantially zero, drop below a particular level, or increase above a particular level), an endpoint can be considered to be reached. Various wavelengths, specific to the etch chemistry being used and the material layer being etched, may be used. Furthermore, the etch time can be extended to include a period of over-etch, wherein the over-etch period constitutes a fraction (i.e., 1 to 100%) of the time between initiation of the etch process and the time associated with endpoint detection.

One or more of the etching processes described above may be performed utilizing a plasma processing system such as the one described in FIG. 6. However, the methods discussed are not to be limited in scope by this exemplary presentation.

Although only certain embodiments of this invention have been described in detail above, those skilled in the art will readily appreciate that many modifications are possible in the embodiments without materially departing from the novel teachings and advantages of this invention. For example, although one exemplary process flow is provided for preparing a metal gate structure, other process flows are contemplated. Accordingly, all such modifications are intended to be included within the scope of this invention.

1. A method of patterning a gate structure on a substrate, comprising:
preparing a metal gate structure on a substrate, said metal gate structure including a high dielectric constant (high-k) layer, a first gate layer formed on said high-k layer, and a second gate layer formed on said first gate layer, said first gate layer comprising one or more metal-containing layers;
preparing a mask layer with a pattern overlying said metal gate structure;
transferring said pattern to said second gate layer;
transferring said pattern to said first gate layer;
transferring said pattern in said first gate layer to said high-k layer; and
prior to said transferring said pattern to said high-k layer, passivating an exposed surface of said first gate layer using a nitrogen-containing and/or carbon-containing environment to reduce under-cutting of said first gate layer relative to said second gate layer,
wherein said passivating is performed separately from or in addition to said transferring said pattern to said first gate layer.

2. The method of claim 1, wherein said second gate layer includes a tungsten-containing material.

3. The method of claim 1, wherein said second gate layer includes tungsten.

4. The method of claim 1, wherein said first gate layer includes one or more sub-layers, each of said one or more sub-layers containing a metal or a metal alloy.

5. The method of claim 4, wherein a first sub-layer of said first gate layer includes titanium or a titanium alloy.

6. The method of claim 1, wherein a second sub-layer of said first gate layer includes aluminum or an aluminum alloy.

7. The method of claim 6, wherein said high-k layer includes hafnium or lanthanum.

8. The method of claim 1, wherein said high-k layer comprises hafnium dioxide (HfO₂), hafnium silicate (HfSiO), or nitrided hafnium silicate (HfSiO(N)), or any combination of two or more thereof.

9. The method of claim 1, wherein said nitrogen-containing and/or carbon-containing environment comprises a nitrogen-containing plasma and/or carbon-containing plasma.

10. The method of claim 9, wherein said nitrogen-containing plasma contains as an incipient ingredient N₂, or NH₃, or a combination thereof.

11. The method of claim 9, wherein said carbon-containing plasma contains as an incipient ingredient a hydrocarbon-containing gas.

12. The method of claim 11, wherein said carbon-containing plasma contains as an incipient ingredient at least one of C₂H₄, CH₄, C₂H₂, C₂H₆, C₃H₄, C₃H₆, C₃H₈, C₄H₆, C₄H₈, C₄H₁₀, C₆H₈, C₆H₁₀, C₆H₆, C₆H₁₀, and C₆H₁₂.

13. The method of claim 1, further comprising:
selecting a substrate temperature less than about 250 degrees C. during said transferring said pattern to said high-k layer to reduce under-cutting of said first gate layer.

14. The method of claim 1, further comprising:
selecting a substrate temperature less than about 220 degrees C. during said transferring said pattern to said high-k layer to reduce under-cutting of said first gate layer.

15. The method of claim 1, wherein said pattern is transferred to said first gate layer using a halogen-containing gas containing one or more gases selected from a group consisting of Cl₂, HBr, and BCl₃.

16. The method of claim 1, wherein said pattern is transferred to said first gate layer using Cl₂, BCl₃, and Ar.

17. The method of claim 1, wherein said pattern is transferred to said high-k layer using a halogen-containing gas containing one or more gases selected from the group consisting of Cl₂, HBr, and BCl₃.

18. The method of claim 17, wherein said pattern is transferred to said high-k layer using a composition containing BCl₃ and He.

19. The method of claim 17, wherein said pattern is transferred to said high-k layer using a composition further containing a hydrocarbon gas and/or a nitrogen-containing gas.

20. A method of patterning a gate structure on a substrate, comprising:
preparing a metal gate structure on a substrate, said metal gate structure including a high-k layer, a metal alloy layer formed on said high-k layer, and a gate layer formed on said metal alloy layer, said metal alloy layer comprising an aluminum-alloy and/or titanium-alloy;
preparing a mask layer with a pattern overlying said metal gate structure;
transferring said pattern to said gate layer;
transferring said pattern to said metal alloy layer;
transferring said pattern in said metal alloy layer to said high-k layer; and
passivating an exposed surface of said metal alloy layer using a nitrogen-containing environment and/or carbon-containing environment to reduce under-cutting of said metal alloy layer relative to said gate layer.
